(19) United States
(12) Patent Application Publication
(10) Pub. No.: US 2019/0361306 A1
(43) Pub. Date: Nov. 28, 2019

(54) SEMICONDUCTOR SUBSTRATE AND DISPLAY PANEL INCLUDING THE SAME

(71) Applicant: Samsung Electronics Co., Ltd., Suwon-si (KR)

(72) Inventor: Myoungsoo KIM, Hwaseong-si (KR)

(73) Assignee: Samsung Electronics Co., Ltd., Suwon-si (KR)

(21) Appl. No.: 16/256,085

(22) Filed: Jan. 24, 2019

(30) Foreign Application Priority Data
May 28, 2018 (KR) 10-2018-0060071

(51) Int. Cl. G02F 1/1362; G02F 1/1343; G02F 1/1335; H01L 27/32; H01L 51/52

(52) U.S. Cl. CPC G02F 1/136277; G02F 1/13439; G02F 1/133553; H01L 2251/5315; G02F 1/134336; H01L 51/5271; H01L 51/5218; H01L 27/3244

(57) ABSTRACT

Disclosed are semiconductor substrates and display panels including the same. The semiconductor substrate comprises at least a pair of first electrodes spaced apart from each other on a substrate, a buried pattern between the first electrodes and surrounding a lateral surface of each of the first electrodes, a dielectric pattern between the buried pattern and each of the first electrodes, and a plurality of transistors on the substrate and connected to corresponding first electrodes. The buried pattern comprises a conductive material.

### CROSS-REFERENCE TO RELATED APPLICATION

This U.S. nonprovisional application claims priority under 35 U.S.O § 119 to Korean Patent Application No. 10-2018-0060071 filed on May 28, 2018 in the Korean Intellectual Property Office, the entire contents of which are hereby incorporated by reference.

### BACKGROUND

Example embodiments of the present inventive concepts relate to a semiconductor substrate and/or a display panel including the same.

With the rapid development of semiconductor technology, various electronic products such as computers have been downsized, and accordingly, sizes of display devices have been required to be reduced. A microdisplay may be a small display having a screen size that usually less than two inches diagonal, and due to the small screen size, an optical system may be used to magnify the screen size.

A liquid crystal on silicon (LCOS) display, one of reflective microdisplays, is configured such that a liquid cell is formed on a semiconductor substrate including a complementary metal oxide semiconductor (CMOS) circuit for controlling each pixel, unlike conventional liquid displays. In this case, components of each pixel and a switching circuit may be highly integrated on the semiconductor substrate, and thus the LCOS display has an advantage of achieving a small size of about 1 inch and high resolution equal to or greater than Extended Graphics Array (XGA). An organic light emitting diode on silicon (OLEDOS) display, one of self-emissive microdisplays, is configured such that an anode electrode, an organic light emitting layer, and a cathode electrode are formed on a semiconductor substrate including a complementary metal oxide semiconductor (CMOS) circuit for controlling each pixel.

### SUMMARY

Some example embodiments of the present inventive concepts provide a semiconductor substrate with improved flatness used for a display panel.

Some example embodiments of the present inventive concepts provide a display panel with reduced or (alternatively, minimized) defects.

According to some example embodiments of the present inventive concepts, a semiconductor substrate may include at least two first electrodes spaced apart from each other on a substrate; a buried pattern between the at least two first electrodes such that the buried pattern surrounds a lateral surface of each of the at least two first electrodes, the buried pattern including a conductive material; a dielectric pattern between the buried pattern and each of the at least two first electrodes; and a plurality of transistors on the substrate, the plurality of transistors being connected to corresponding ones of the at least two first electrodes.

According to some example embodiments of the present inventive concepts, a semiconductor substrate may include a plurality of first electrodes spaced apart from each other in a first direction and a second direction on a substrate, the first direction and the second direction being parallel to a top surface of the substrate and intersecting each other; a buried pattern filling a portion of a gap between the plurality of first electrodes such that the buried pattern surrounds a lateral surface of each of the plurality of first electrodes, the buried pattern including a conductive material; and a dielectric pattern filling a remaining portion of the gap such that the dielectric pattern is interposed between the buried pattern and the lateral surface of each of the plurality of first electrodes.

According to some example embodiments of the present inventive concepts, a display panel may include at least two first electrodes spaced apart from each other on a substrate; a buried pattern between the at least two first electrodes, the buried pattern including a conductive material; a dielectric pattern between the buried pattern and each of the at least two first electrodes; a second electrode covering the at least two first electrodes, the buried pattern, and the dielectric pattern; and a liquid crystal layer between the second electrode and each of the at least two first electrodes, the buried pattern, and the dielectric pattern.

### BRIEF DESCRIPTION OF THE DRAWINGS

FIG. 1 illustrates a plan view showing a semiconductor substrate for a display panel according to some example embodiments of the present inventive concepts.

FIG. 2 illustrates a cross-sectional view taken along lines I-I′ and II-II′ of FIG. 1.

FIG. 3 illustrates an enlarged view showing section A of FIG. 2.

FIGS. 4 to 11 illustrate cross-sectional views taken along lines I-I′ and II-II′ of FIG. 1, showing a method of manufacturing a semiconductor substrate for a display panel according to some example embodiments of the present inventive concepts.

FIG. 12 illustrates an enlarged view showing section B of FIG. 11.

FIG. 13 illustrates a plan view showing a display panel including a semiconductor substrate according to some example embodiments of the present inventive concepts.

FIG. 14 illustrates a cross-sectional view taken along line I-I′ of FIG. 13, showing an example of a display panel including a semiconductor substrate according to some example embodiments of the present inventive concepts.

FIG. 15 illustrates a cross-sectional view taken along line I-I′ of FIG. 13, showing an example of a display panel including a semiconductor substrate according to some example embodiments of the present inventive concepts.

### DETAILED DESCRIPTION

Some example embodiments of the present inventive concepts will be described below in detail with reference to the accompanying drawings.

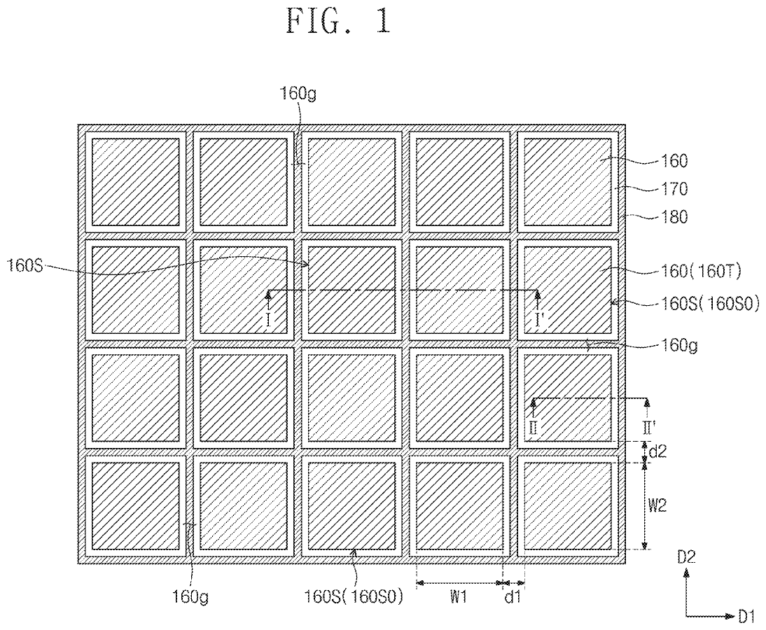

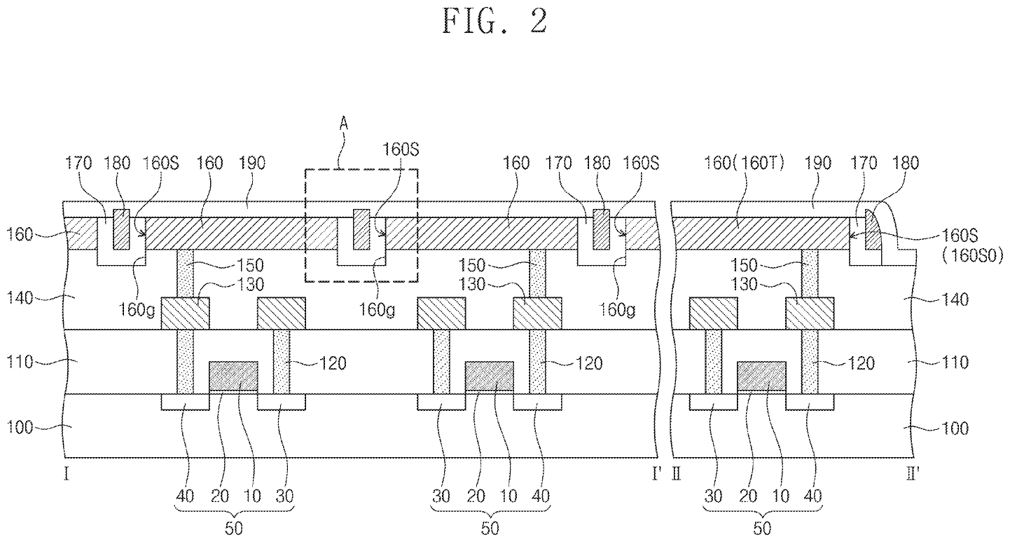

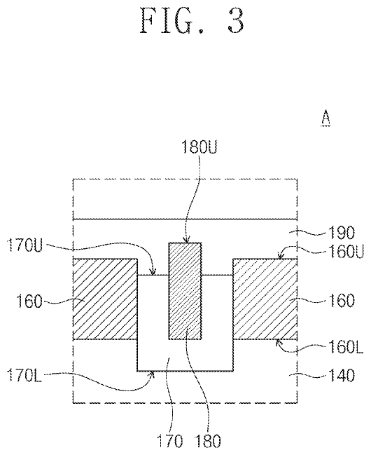

FIG. 1 illustrates a plan view showing a semiconductor substrate for a display panel according to some example embodiments of the present inventive concepts. FIG. 2 illustrates a cross-sectional view taken along lines I-I′ and II-II′ of FIG. 1. FIG. 3 illustrates an enlarged view showing section A of FIG. 2.

Referring to FIGS. 1 and 2, transistors 50 may be provided on a substrate 100. The substrate 100 may be or include a silicon substrate, a germanium substrate, or a silicon-on-insulator (SOI) substrate. The substrate 100 may be, for example, a single crystalline silicon substrate. The transistors 50 may be or include metal oxide semiconductor field effect transistors (MOSFETs). For example, each of the transistors 50 may include a gate electrode 10 on the substrate 100, a gate dielectric pattern 20 between the gate electrode 10 and the substrate 100, and source/drain regions 30 and 40 on opposite sides of the gate electrode 10. The source/drain regions 30 and 40 may be impurity-doped areas formed in the substrate 100 on opposite sides of the gate electrode 10. For example, the gate electrode 10 may include one or more of doped semiconductor, conductive metal nitride (e.g., titanium nitride or tantalum nitride), and metal (e.g., aluminum or tungsten), and the gate dielectric pattern 20 may include silicon oxide. The source/drain regions 30 and 40 may have a different conductivity from that of the substrate 100. The source/drain regions 30 and 40 may include N-type impurities (e.g., phosphorous (P) or arsenic (As)) or P-type impurities (e.g., boron (B)).

A lower interlayer dielectric layer 110 may be provided on the substrate 100, covering the transistors 50. The lower interlayer dielectric layer 110 may include one or more of an oxide layer, a nitride layer, and an oxynitride layer. The lower interlayer dielectric layer 110 may be provided therein with lower conductive contacts 120 connected to corresponding source/drain regions 30 and 40 of the transistors 50. The lower conductive contacts 120 may include a conductive material.

Line patterns 130 may be provided on the lower interlayer dielectric layer 110. Each of the lower conductive contacts 120 may be connected to a corresponding one of the line patterns 130. One of the source/drain regions 30 and 40 of each of the transistors 50 may be connected to a corresponding one of the line patterns 130 through the lower conductive contact 120 coupled to the one (e.g., the source region 30) of the source/drain regions 30 and 40. The other of the source/drain regions 30 and 40 of each of the transistors 50 may be connected to a corresponding one of the line patterns 130 through the lower conductive contact 120 coupled to the other (e.g., the drain region 40) of the source/drain regions 30 and 40. The line patterns 130 may include, for example, metal. Although not shown, additional line patterns may be provided between the lower interlayer dielectric layer 110 and the line patterns 130. In this case, each of the lower conductive contacts 120 may be electrically connected to a corresponding one of the line pattern 130 through one or more corresponding additional line patterns. The additional line patterns may include, for example, metal.

An upper interlayer dielectric layer 140 may be provided on the lower interlayer dielectric layer 110, covering the line patterns 130. The upper interlayer dielectric layer 140 may include one or more of an oxide layer, a nitride layer, and an oxynitride layer.

First electrodes 160 may be provided on the upper interlayer dielectric layer 140. The first electrodes 160 may be horizontally spaced apart from each other on the upper interlayer dielectric layer 140. For example, the first electrodes 160 may be spaced apart from each other in a first direction D1 and a second direction D2 that are parallel to a top surface 100U of the substrate 100 and intersect each other. Each of the first electrodes 160 may have a first width W1 in the first direction D1 and a second width W2 in the second direction D2. A pair of first electrodes 160 may be directly adjacent to each other in the first direction D1 at a first distance dl less than the first width W1. A pair of first electrodes 160 may be directly adjacent to each other in the second direction D2 at a second distance d2 less than the second width W2. The first electrodes 160 may include metal, such as aluminum (Al) and/or titanium (Ti).

Each of the first electrodes 160 may be connected through an upper conductive contact 150 to a corresponding one of the line patterns 130. The upper conductive contact 150 may be provided in the upper interlayer dielectric layer 140, and may penetrate the upper interlayer dielectric layer 140 and have connection with the corresponding line pattern 130. The upper conductive contact 150 may include a conductive material. Each of the first electrodes 160 may be connected to a terminal of a corresponding one of the transistors 50 through the upper conductive contact 150, the line pattern 130, and the lower conductive contact 120 that are coupled to the each of the first electrodes 160. For example, the first electrodes 160 may be connected to corresponding ones (e.g., the drain regions 40) of the source/drain regions 30 and 40 of the transistors 50. The transistors 50 may be configured to apply voltages to corresponding first electrodes 160.

The upper interlayer dielectric layer 140 may be provided thereon with a buried pattern 180 between the first electrodes 160. The buried pattern 180 may partially fill a gap 160g between the first electrodes 160. When viewed in plan, the buried pattern 180 may have a net or grid shape extending along the first and second directions D1 and D2 between the first electrodes 160. The buried pattern 180 may surround and be spaced apart from a lateral surface 160S of each of the first electrodes 160.

The buried pattern 180 may be interposed between a pair of first electrodes 160 directly adjacent to each other. The buried pattern 180 may partially fill the gap 160g between the pair of first electrodes 160. The buried pattern 180 may surround and be spaced apart from the lateral surface 160S of each of the pair of first electrodes 160. The buried pattern 180 may include a conductive material. The buried pattern 180 may include metal, for example, one or more of titanium (Ti), titanium nitride (TiN), and tungsten (W).

The upper interlayer dielectric layer 140 may be provided thereon with a dielectric pattern 170 between the buried pattern 180 and each of the first electrodes 160. The dielectric pattern 170 may fill a remaining portion of the gap 160g between the first electrodes 160. The dielectric pattern 170 may surround and contact the lateral surface 160S of each of the first electrodes 160. The buried pattern 180 may be spaced apart from the lateral surface 160S of each of the first electrodes 160 with the dielectric pattern 170 interposed between the buried pattern 180 and each of the first electrodes 160. The dielectric pattern 170 may extend between the buried pattern 180 and the upper interlayer dielectric layer 140. The buried pattern 180 may be spaced apart from the upper interlayer dielectric layer 140 across the dielectric pattern 170.

The dielectric pattern 170 may be interposed between a pair of first electrodes 160 directly adjacent to each other. The dielectric pattern 170 may fill a remaining portion of the gap 160g between the pair of first electrodes 160. The dielectric pattern 170 may be interposed between the buried pattern 180 and each of the pair of first electrodes 160, and may extend between the buried pattern 180 and the upper interlayer dielectric layer 140. When viewed in cross-section, the dielectric pattern 170 may have a U shape between the pair of first electrodes 160. The dielectric pattern 170 may include one or more of oxide, nitride, and oxynitride. For example, the dielectric pattern 170 may include one or more of silicon oxide, silicon nitride, and silicon oxynitride.

Referring to FIGS. 2 and 3, the buried pattern 180 may protrude from an uppermost top surface 170U of the dielectric pattern 170. For example, the buried pattern 180 may have a top surface 180U at a height greater than that of the uppermost top surface 170U of the dielectric pattern 170. In this description, the term “height” may mean a distance from the top surface 100U of the substrate 100. The top surface 180U of the buried pattern 180 may be located at a height greater than those of top surfaces 160U of the first electrodes 160. The uppermost top surface 170U of the dielectric pattern 170 may be located at a height substantially the same as or less than those of the top surfaces 160U of the first electrodes 160. In some example embodiments, the dielectric pattern 170 may have a lowermost bottom surface 170L at a height from the substrate 100 less than those of bottom surfaces 160L of the first electrodes 160.

Referring back to FIGS. 1 and 2, the first electrodes 160 may include an outermost first electrode 160T disposed on an outermost column. The outermost first electrode 160T may have an outermost lateral surface 160SO, which outermost lateral surface 160SO may not face the lateral surface 160S of the first electrode 160 adjacent to the outermost first electrode 160T. The buried pattern 180 may cover the outermost lateral surface 160SO of the outermost first electrode 160T. For example, the buried pattern 180 may have a spacer shape covering the outermost lateral surface 160SO of the outermost first electrode 160T. The dielectric pattern 170 may be interposed between the buried pattern 180 and the outermost lateral surface 160SO of the outermost first electrode 160T, and may extend between the buried pattern 180 and the upper interlayer dielectric layer 140. When viewed in cross-section, the dielectric pattern 170 may have an L shape on the outermost lateral surface 160SO of the outermost first electrode 160T.

The upper interlayer dielectric layer 140 may be provided thereon with a passivation layer 190 covering the first electrodes 160, the buried pattern 180, and the dielectric pattern 170. The passivation layer 190 may include one or more of an oxide layer, a nitride layer, and an oxynitride layer. As shown in FIG. 3, when the uppermost top surface 170U of the dielectric pattern 170 is located at a height less than those of the top surfaces 160U of the first electrodes 160, the passivation layer 190 may partially extend between the first electrodes 160.

A semiconductor substrate for a display panel may benefit from having a flat surface to minimize or reduce defects of an upper structure which may be formed on the semiconductor substrate. When the gap 160g between the first electrodes 160 is incompletely filled, such incomplete filling may cause deterioration in surface flatness of the semiconductor substrate, thus leading to defects on the upper surface.

According to example embodiments of the present inventive concepts, the buried pattern 180 and the dielectric pattern 170 may fill the gap 160g between the first electrodes 160. The buried pattern 180 may include a material having an etch selectivity with respect to the dielectric pattern 170, and accordingly loss of the buried pattern 180 may be minimized or reduced when an etching process is performed to form the dielectric pattern 170. The gap 160g between the first electrodes 160 may then be easily filled with the buried pattern 180 and the dielectric pattern 170. As a result, it may be possible to improve surface flatness of the semiconductor substrate for a display panel.

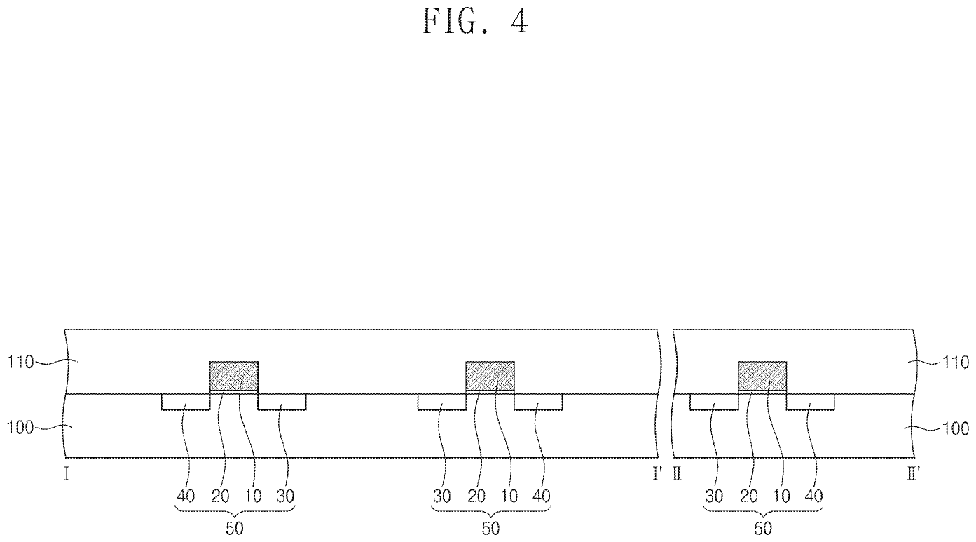

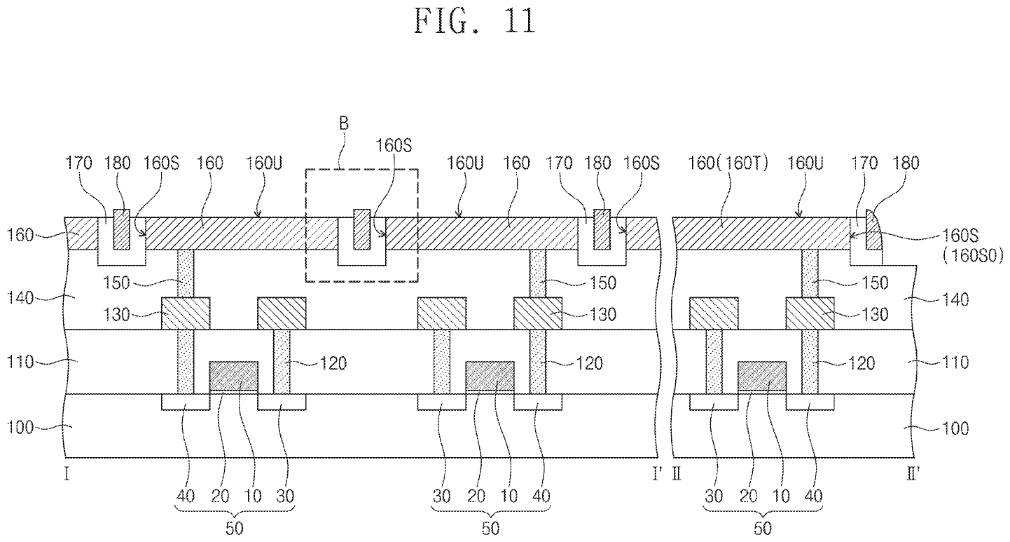

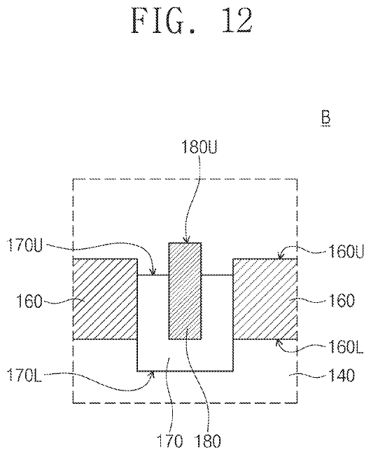

FIGS. 4 to 11 illustrate cross-sectional views taken along lines I-I′ and II-II′ of FIG. 1, showing a method of manufacturing a semiconductor substrate for a display panel according to some example embodiments of the present inventive concepts. FIG. 12 illustrates an enlarged view showing section B of FIG. 11. In the embodiments that follow, a repetitive description to the semiconductor substrate for a display panel discussed with reference to FIGS. 1 to 3 will be avoided for brevity of explanation.

Referring to FIG. 4, transistors 50 may be formed on a substrate 100. Each of the transistors 50 may include a gate electrode 10 on the substrate 100, a gate dielectric pattern 20 between the gate electrode 10 and the substrate 100, and source/drain regions 30 and 40 on opposite sides of the gate electrode 10. For example, the formation of the transistors 50 may include forming a gate dielectric layer on the substrate 100, forming a gate electrode layer on the gate dielectric layer, forming a gate mask pattern on the gate electrode layer, and sequentially etching the gate electrode layer and the gate dielectric layer using the gate mask pattern as an etching mask. The gate electrode layer and the gate dielectric layer may be etched to respectively form the gate electrode 10 and the gate dielectric pattern 20. The formation of the transistors 50 may further include forming the source/drain regions 30 and 40 by implanting impurities into the substrate 100 on opposite sides of the gate electrode 10. A lower interlayer dielectric layer 110 may be formed on the substrate 100, covering the transistors 50.

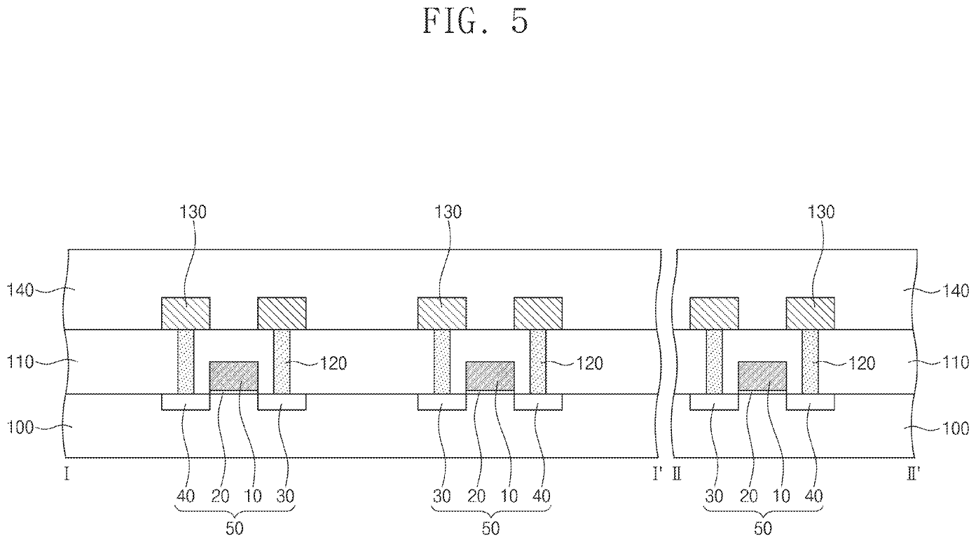

Referring to FIG. 5, lower conductive contacts 120 may be formed in the lower interlayer dielectric layer 110. For example, the formation of the lower conductive contacts 120 may include patterning the lower interlayer dielectric layer 110 to form lower contact holes exposing the source/drain regions 30 and 40 of the transistors 50, forming on the lower interlayer dielectric layer 110 a lower conductive layer to fill the lower contact holes, and performing a planarization process on the lower conductive layer until the lower interlayer dielectric layer 110 is exposed. The planarization process may form the lower conductive contacts 120 in corresponding lower contact holes. Line patterns 130 may be formed on the lower interlayer dielectric layer 110. For example, the formation of the line patterns 130 may include forming on the lower interlayer dielectric layer 110 a line conductive layer to cover the lower conductive contacts 120, and then patterning the line conductive layer. Each of the lower conductive contacts 120 may be connected to a corresponding one of the line patterns 130. An upper interlayer dielectric layer 140 may be formed on the lower interlayer dielectric layer 110, covering the line patterns 130.

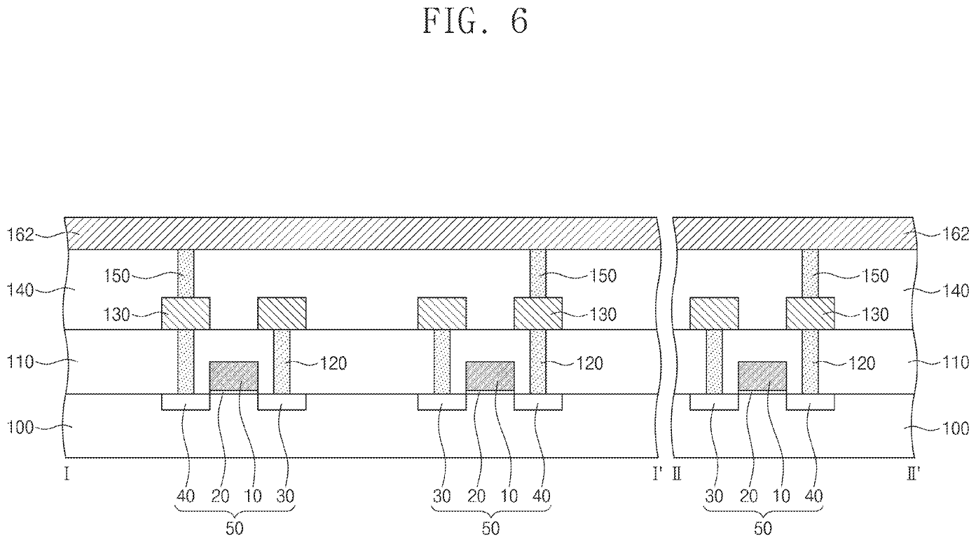

Referring to FIG. 6, upper conductive contacts 150 may be formed in the upper interlayer dielectric layer 140. For example, the formation of the upper conductive contacts 150 may include patterning the upper interlayer dielectric layer 140 to form upper contact holes exposing corresponding top surfaces of the line patterns 130, forming on the upper interlayer dielectric layer 140 an upper conductive layer to fill the upper contact holes, and performing a planarization process on the upper conductive layer until the upper interlayer dielectric layer 140 is exposed. The planarization process may form the upper conductive contacts 150 in corresponding upper contact holes. A first electrode layer 162 may be formed on the upper interlayer dielectric layer 140, covering the upper conductive contacts 150. The first electrode layer 162 may include metal, such as aluminum (Al) and/or titanium (Ti), and may be formed by performing, for example, a sputtering deposition process.

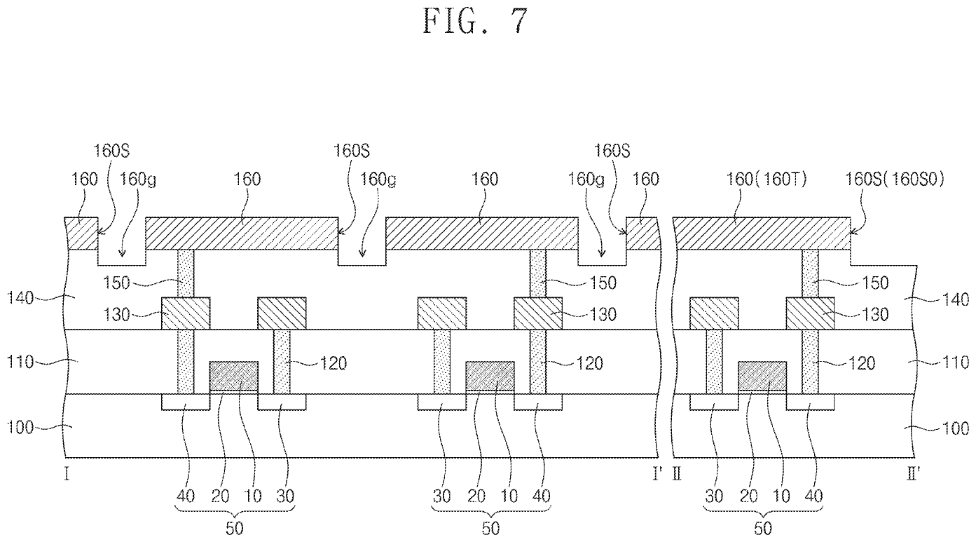

Referring to FIGS. 1 and 7, the first electrode layer 162 may be patterned to form first electrodes 160 on the upper interlayer dielectric layer 140. The first electrodes 160 may be spaced apart from each other along the first and second directions D1 and D2 on the upper interlayer dielectric layer 140. For example, the formation of the first electrodes 160 may include forming mask patterns defining areas where the first electrodes 160 are formed, on the first electrode layer 162, and performing an etching process to etch the first electrode layer 162 using the mask patterns as an etching mask. In some example embodiments, during the etching process on the first electrode layer 162, the upper interlayer dielectric layer 140 may be recessed on its upper portion between the first electrodes 160. The etching process on the first electrode layer 162 may form a gap 160g between the first electrodes 160. The gap 160g may expose a lateral surface 160S of each of the first electrodes 160 and a top surface of the upper interlayer dielectric layer 140 between the first electrodes 160.

Each of the first electrodes 160 may have a first width W1 in the first direction D1 and a second width W2 in the second direction D2. A pair of first electrodes 160 may be directly adjacent to each other in the first direction D1 at a first distance dl less than the first width W1. The first distance dl may correspond to a width of the gap 160g between the pair of first electrodes 160 directly adjacent to each other in the first direction D1. A pair of first electrodes 160 may be directly adjacent to each other in the second direction D2 at a second distance d2 less than the second width W2. The second distance d2 may correspond to a width of the gap 160g between the pair of first electrodes 160 directly adjacent to each other in the second direction D2.

The first electrodes 160 may include an outermost first electrode 160T disposed on an outermost column. The outermost first electrode 160T may have an outermost lateral surface 160SO, which outermost lateral surface 160SO may not face the lateral surface 160S of the first electrode 160 adjacent to the outermost first electrode 160T. During the etching process on the first electrode layer 162, the upper interlayer dielectric layer 140 which is adjacent to the outermost lateral surface 160SO of the outermost first electrode 160T may be recessed on its upper portion. After the first electrodes 160 are formed, the mask patterns may be removed.

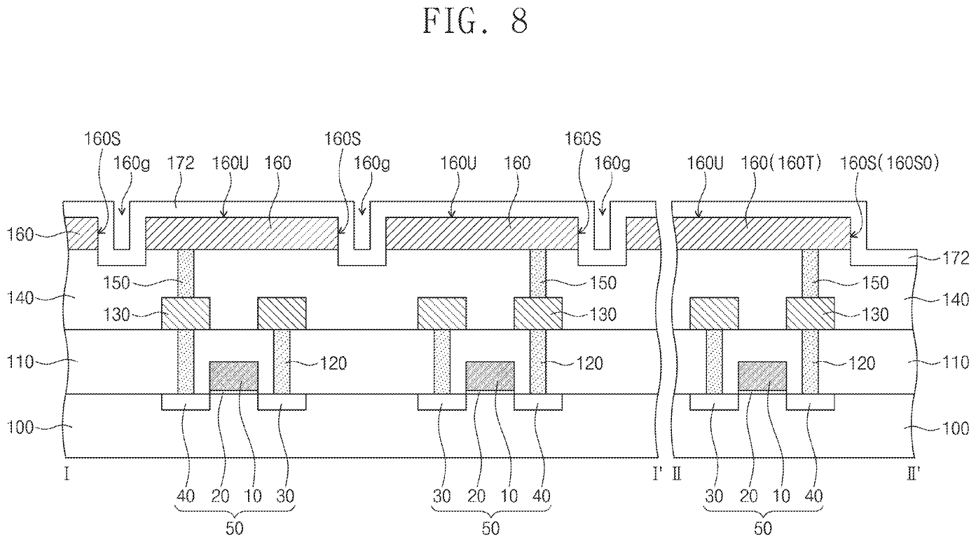

Referring to FIGS. 1 and 8, a dielectric layer 172 may be formed on the upper interlayer dielectric layer 140, covering the first electrodes 160. The dielectric layer 172 may have a thickness that does not completely fill the gap 160g. The dielectric layer 172 may fill a portion of the gap 160g and have a uniform thickness covering the lateral surfaces 160S of the first electrodes 160, top surfaces 160U of the first electrodes 160, and the top surface of the upper interlayer dielectric layer 140 between the first electrodes 160. The dielectric layer 172 may uniformly cover the outermost lateral surface 160SO of the outermost first electrode 160T and a top surface of the upper interlayer dielectric layer 140 adjacent to the outermost lateral surface 160SO. The dielectric layer 172 may include one or more of oxide, nitride, and oxynitride, and may be formed by performing, for example, a chemical vapor deposition process.

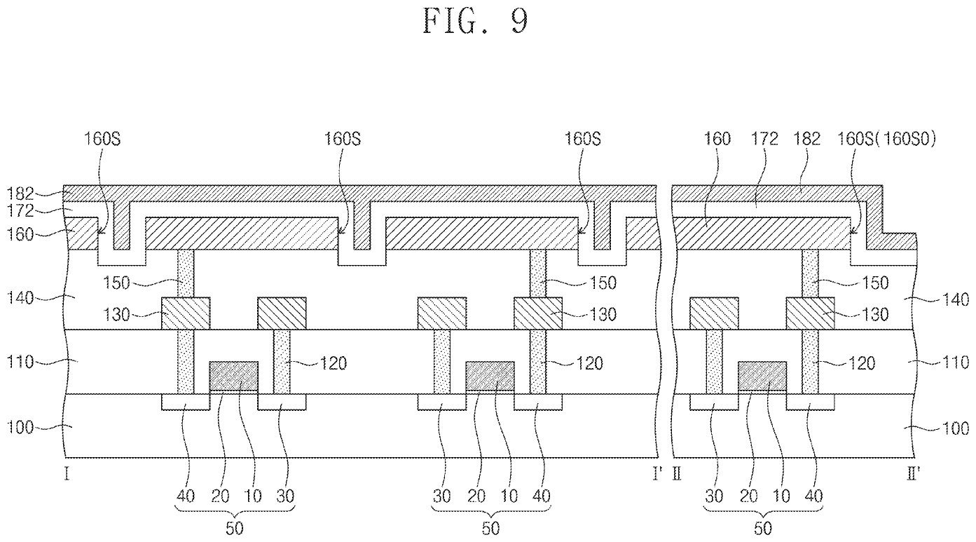

Referring to FIGS. 1 and 9, a buried layer 182 may be formed on the dielectric layer 172. The buried layer 182 may fill a remaining portion of the gap 160g and have a uniform thickness covering the outermost lateral surface 160SO of the outermost first electrode 160T and the top surface of the upper interlayer dielectric layer 140 adjacent to the outermost lateral surface 160SO. The buried layer 182 may include a material having an etch selectivity with respect to the dielectric layer 172. For example, the buried layer 182 may include a conductive material. The buried layer 182 may include metal, for example, one or more of titanium (Ti), titanium nitride (TiN), and tungsten (W). The buried layer 182 may be formed by performing, for example, one or more of a chemical vapor deposition process, an atomic layer deposition process, and a sputtering deposition process.

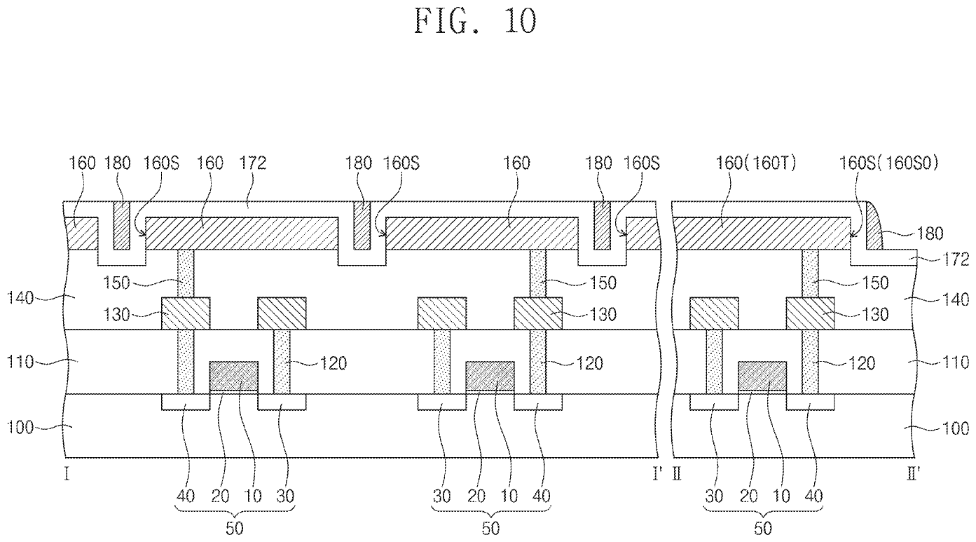

Referring to FIGS. 1 and 10, the buried layer 182 may be etched to form a buried pattern 180. The formation of the buried pattern 180 may include that the buried layer 182 is etched by an anisotropic etching process under an etching condition having an etch selectivity with respect to the dielectric layer 172. For example, the anisotropic etching process on the buried layer 182 may include performing an etch-back process on the buried layer 182 until the dielectric layer 172 is exposed. The buried pattern 180 may be interposed between the first electrodes 160, and when viewed in plan, may have a net or grid shape extending along the first and second directions D1 and D2 between the first electrodes 160. The buried pattern 180 may surround and be spaced apart from the lateral surface 160S of each of the first electrodes 160. The buried pattern 180 may have a spacer shape covering the outermost lateral surface 160SO of the outermost first electrode 160T.

Referring to FIGS. 1 and 11, the dielectric layer 172 may be etched to form a dielectric pattern 170. The formation of the dielectric pattern 170 may include that the dielectric layer 172 is etched by an anisotropic etching process under an etching condition having an etch selectivity with respect to the buried pattern 180 and the first electrodes 160. For example, the anisotropic etching process on the dielectric layer 172 may include performing an etch-back process on the dielectric layer 172 until the top surfaces 160U of the first electrodes 160 are exposed. Because the dielectric layer 172 is anisotropically etched under the etching condition having an etch selectivity with respect to the buried pattern 180, the buried pattern 180 may minimize or reduce its loss during the anisotropic etching process on the dielectric layer 172. During the anisotropic etching process on the dielectric layer 172, the upper interlayer dielectric layer 140 which is adjacent to the outermost lateral surface 160SO of the outermost first electrode 160T may be exposed on its top surface.

The dielectric pattern 170 may be interposed between the buried pattern 180 and each of the first electrodes 160, and may fill a remaining portion of the gap 160g between the first electrodes 160. The dielectric pattern 170 may surround the lateral surface 160S of each of the first electrodes 160, and the buried pattern 180 may be spaced apart from the lateral surface 160S of each of the first electrodes 160 with the dielectric pattern 170 between the buried pattern 180 and each of the first electrodes 160. The dielectric pattern 170 may extend between the buried pattern 180 and the upper interlayer dielectric layer 140. The buried pattern 180 may be spaced apart from the upper interlayer dielectric layer 140 across the dielectric pattern 170. When viewed in cross-section, the dielectric pattern 170 may have a U shape between a pair of first electrodes 160 directly adjacent to each other. The dielectric pattern 170 may be interposed between the buried pattern 180 and the outermost lateral surface 160SO of the outermost first electrode 160T, and may extend between the buried pattern 180 and the upper interlayer dielectric layer 140. When viewed in cross-section, the dielectric pattern 170 may have an L shape on the outermost lateral surface 160SO of the outermost first electrode 160T.

Referring to FIGS. 11 and 12, because the dielectric layer 172 is anisotropically etched under the etching condition having an etch selectivity with respect to the buried pattern 180, the buried pattern 180 may protrude from an uppermost top surface 170U of the dielectric pattern 170. For example, the buried pattern 180 may have a top surface 180U at a height greater than that of the uppermost top surface 170U of the dielectric pattern 170. The top surface 180U of the buried pattern 180 may be located at a height greater than those of the top surfaces 160U of the first electrodes 160. The uppermost top surface 170U of the dielectric pattern 170 may be located at a height substantially the same as or less than those of the top surfaces 160U of the first electrodes 160. In some example embodiments, as discussed with reference to FIGS. 1 and 7, when the first electrode layer 162 is etched, the upper interlayer dielectric layer 140 may be recessed on its upper portion between the first electrodes 160. In such cases, the dielectric pattern 170 may have a lowermost bottom surface 170L at a height from the substrate 100 less than those of bottom surfaces 160L of the first electrodes 160.

Referring back to FIGS. 1 and 2, a passivation layer 190 may be formed on the upper interlayer dielectric layer 140, and may cover the first electrodes 160, the buried pattern 180, and the dielectric pattern 170. The passivation layer 190 may be formed by performing, for example, a chemical vapor deposition process.

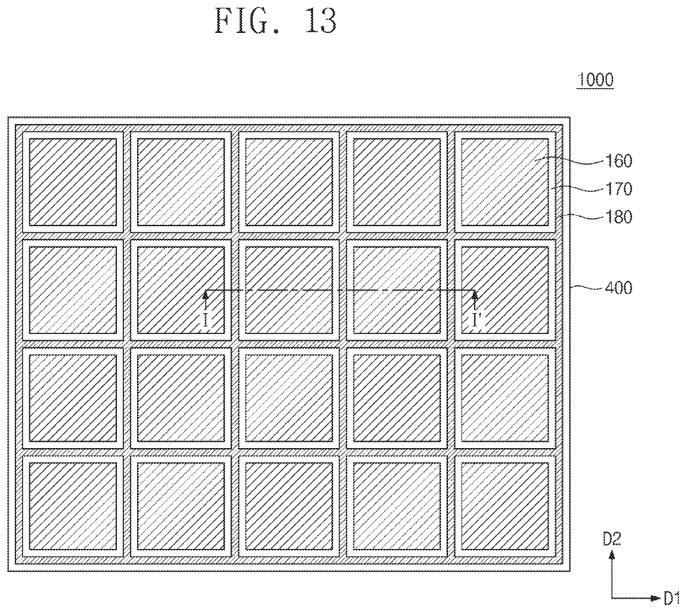

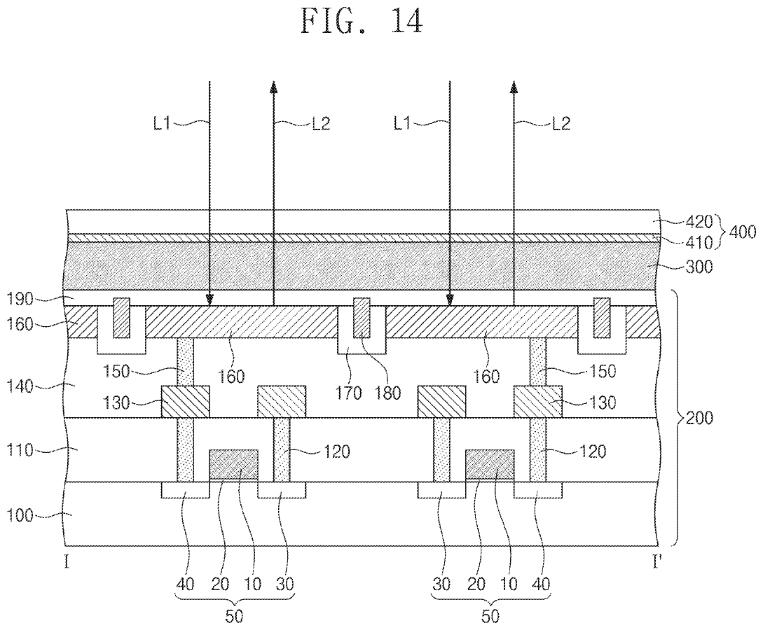

FIG. 13 illustrates a plan view showing a display panel including a semiconductor substrate according to some example embodiments of the present inventive concepts. FIG. 14 illustrates a cross-sectional view taken along line I-I′ of FIG. 13, showing an example of a display panel including a semiconductor substrate according to some example embodiments of the present inventive concepts.

Referring to FIGS. 13 and 14, a display panel 1000 may include a semiconductor substrate 200, an upper substrate 400 on the semiconductor substrate 200, and a liquid crystal layer 300 between the semiconductor substrate 200 and the upper substrate 400. The semiconductor substrate 200 may be the semiconductor substrate 100 discussed with reference to FIGS. 1 to 3 according to some example embodiments of the present inventive concepts.

The liquid crystal layer 300 may be provided on the passivation layer 190 of the semiconductor substrate 200. The liquid crystal layer 300 may include liquid crystals dispersed therein. The upper substrate 400 may include a second electrode 410 and a transparent substrate 420 sequentially stacked on the liquid crystal layer 300. The second electrode 410 may be a transparent electrode including indium tin oxide (ITO), and the transparent substrate 420 may be a glass substrate. The second electrode 410 may be configured to apply a reference voltage to the liquid crystal layer 300. The formation of the liquid crystal layer 300 may include forming the upper substrate 400 on the semiconductor substrate 200, and then injecting liquid crystals into a space between the semiconductor substrate 200 and the upper substrate 400. In some example embodiments, the semiconductor substrate 200 may be provided thereon with support patterns by which the upper substrate 400 is supported.

The display panel 1000 may be a reflective display panel. In this case, the first electrodes 160 of the semiconductor substrate 200 may serve as reflective mirrors. For example, the display panel 1000 may receive therein an incident light L1 passing through the upper substrate 400, and the incident light L1 may be reflected on the first electrodes 160 of the semiconductor substrate 200. A reflected light L2 may be reflected from the first electrodes 160, and then may be emitted from the display panel 1000 through the liquid crystal layer 300 and the upper substrate 400. An optical state of liquid crystals in the liquid crystal layer 300 may be changed due to a difference in potential between the first electrodes 160 of the semiconductor substrate 200 and the second electrode 410 of the upper substrate 400. For example, a molecular arrangement of liquid crystals in the liquid crystal layer 300 may be changed due to an electric field between potentials of the first and second electrodes 160 and 410, and accordingly, the reflected light L2 may have a chromaticity determined by electro-optical characteristics of the liquid crystals.

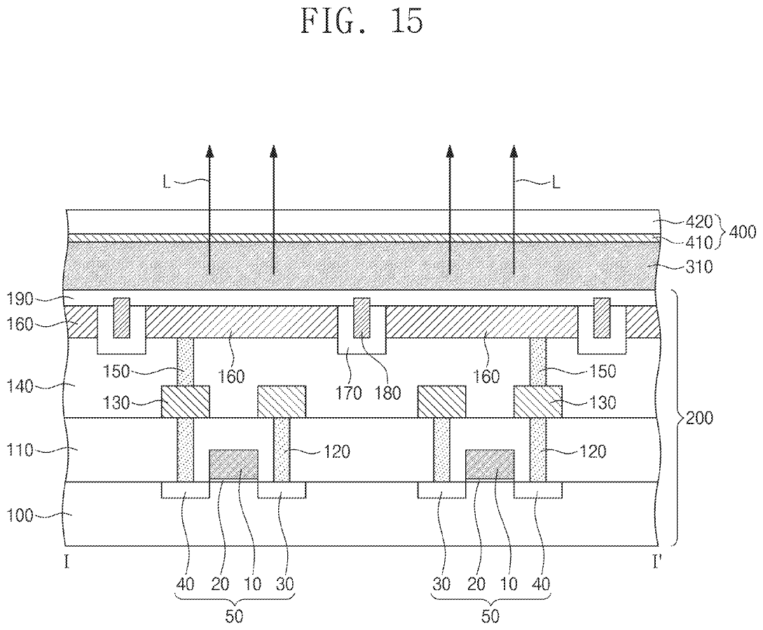

FIG. 15 illustrates a cross-sectional view taken along line I-I′ of FIG. 13, showing an example of a display panel including a semiconductor substrate according to some example embodiments of the present inventive concepts.

Referring to FIGS. 13 and 15, a display panel 1000 may include a semiconductor substrate 200, an upper substrate 400 on the semiconductor substrate 200, and a light emitting layer 310 between the semiconductor substrate 200 and the upper substrate 400. The semiconductor substrate 200 may be the semiconductor substrate 100 discussed with reference to FIGS. 1 to 3 according to some example embodiments of the present inventive concepts.

The light emitting layer 310 may be provided on the passivation layer 190 of the semiconductor substrate 200. The light emitting layer 310 may include an organic light emitting layer. The upper substrate 400 may include a second electrode 410 and a transparent substrate 420 sequentially stacked on the light emitting layer 310. The second electrode 410 may be a transparent electrode including indium tin oxide (ITO), and the transparent substrate 420 may be a glass substrate. The light emitting layer 310, the second electrode 410, and the transparent substrate 420 may be sequentially stacked on the semiconductor substrate 200.

The display panel 1000 may be a self-emissive display panel. For example, the first electrodes 160 of the semiconductor substrate 200 may serve as anode electrodes from which electrons are emitted, and the second electrode 410 may serve as an cathode electrode from which holes are emitted. A light L may be emitted from the light emitting layer 310 in which electrons and holes are recombined, which electrons are provided from the first electrodes 160 and which holes are provided from the second electrode 410.

When the semiconductor substrate 200 becomes poor in surface flatness, defects may be increasingly produced in an upper structure (e.g., the liquid crystal layer 300 or the light emitting layer 310) which is formed on the semiconductor substrate 200.

According to example embodiments of the present inventive concepts, the buried pattern 180 and the dielectric pattern 170 may easily fill the gap 160g between the first electrodes 160 of the semiconductor substrate 200, and thus the semiconductor substrate 200 may improve in surface flatness. Accordingly, defects may be minimally or insignificantly produced in an upper structure (e.g., the liquid crystal layer 300 or the light emitting layer 310) formed on the semiconductor substrate 200. Thus, it may be possible to minimize or reduce defects of the display panel 1000 including the semiconductor substrate 200.

In addition, when the display panel 1000 is a reflective display panel, because the buried pattern 180 includes metal, the incident light L1 may be reflected not only on the first electrodes 160 but also on the buried pattern 180. In conclusion, the display panel 1000 may increase in reflectivity.

According to example embodiments of the present inventive concepts, a buried pattern and a dielectric pattern may easily fill a gap between first electrodes of a semiconductor substrate used for a display panel. As a result, the semiconductor substrate may improve in surface flatness. Furthermore, the improvement in surface flatness of the semiconductor substrate may minimize or reduce defects of an upper structure formed on the semiconductor substrate. Therefore, it may be possible to minimize or reduce defects of the display panel including the semiconductor substrate.

The aforementioned description provides some example embodiments for explaining example embodiments of the present inventive concepts. However, example embodiments of the present inventive concepts are not limited to the example embodiments described above, and it will be understood by one of ordinary skill in the art that variations in form and detail may be made therein without departing from the spirit of example embodiments of the present inventive concepts.

What is claimed is:

1. A semiconductor substrate, comprising:
at least two first electrodes spaced apart from each other on a substrate;
a buried pattern between the at least two first electrodes such that the buried pattern surrounds a lateral surface of each of the at least two first electrodes, the buried pattern including a conductive material;
a dielectric pattern between the buried pattern and each of the at least two first electrodes; and
a plurality of transistors on the substrate, the plurality of transistors being connected to corresponding ones of the at least two first electrodes.

2. The semiconductor substrate of claim 1, wherein
the dielectric pattern surrounds the lateral surface of each of the at least two first electrodes, and
the buried pattern is spaced apart from the lateral surface of each of the at least two first electrodes with the dielectric pattern between the buried pattern and each of the at least two first electrodes.

3. The semiconductor substrate of claim 2, further comprising:
an interlayer dielectric layer on the substrate such that the interlayer dielectric layer covers the plurality of transistors, wherein
the at least two first electrodes, the buried pattern, and the dielectric pattern are on the interlayer dielectric layer, and
the dielectric pattern extends between the buried pattern and the interlayer dielectric layer.

4. The semiconductor substrate of claim 1, wherein the buried pattern comprises metal.

5. The semiconductor substrate of claim 1, wherein each of the plurality of transistors comprises:
a gate electrode on the substrate; and
a source region on the substrate on a first side of the gate electrode and a drain region on the substrate on a second side of the gate electrode, wherein
each of the at least two first electrodes is connected to the drain region of corresponding one of the plurality of transistors .

6. The semiconductor substrate of claim 1, wherein a height of a top surface of the buried pattern is greater than that of top surfaces of the at least two first electrodes.

7. The semiconductor substrate of claim 1, wherein a height of a top surface of the buried pattern is greater than that of a top surface of the dielectric pattern.

8. A semiconductor substrate, comprising:
a plurality of first electrodes spaced apart from each other in a first direction and a second direction on a substrate, the first direction and the second direction being parallel to a top surface of the substrate and intersecting each other;
a buried pattern filling a portion of a gap between the plurality of first electrodes such that the buried pattern surrounds a lateral surface of each of the plurality of first electrodes, the buried pattern including a conductive material; and
a dielectric pattern filling a remaining portion of the gap such that the dielectric pattern is interposed between the buried pattern and the lateral surface of each of the plurality of first electrodes.

9. The semiconductor substrate of claim 8, wherein the plurality of first electrodes and the buried pattern comprise metal.

10. The semiconductor substrate of claim 8, wherein the dielectric pattern extends between the buried pattern and the substrate.

11. The semiconductor substrate of claim 8, wherein
each of the plurality of first electrodes has a first width in the first direction and a second width in the second direction,
a first pair of first electrodes among the plurality of first electrodes are directly adjacent to each other in the first direction with a first distance therebetween, the first distance being less than the first width, and
a second pair of first electrodes among the plurality of first electrodes are directly adjacent to each other in the second direction with a second distance therebetween, the second distance being less than the second width.

12. The semiconductor substrate of claim 8, wherein the buried pattern is spaced apart from the lateral surface of each of the plurality of first electrodes with the dielectric pattern between the buried pattern and each of the plurality of first electrodes.

13. The semiconductor substrate of claim 8, wherein a height of a top surface of the buried pattern is greater than that of a top surface of the dielectric pattern.

14. The semiconductor substrate of claim 13, wherein a height of the top surface of the buried pattern is greater than that of top surfaces of the plurality of first electrodes.

15. The semiconductor substrate of claim 8, further comprising:
a plurality of transistors on the substrate; and
an interlayer dielectric layer on the substrate such that the interlayer dielectric layer covers the plurality of transistors, wherein
the plurality of first electrodes, the buried pattern, and the dielectric pattern are disposed on the interlayer dielectric layer, and
each of the plurality of first electrodes is connected to a terminal of a corresponding one of the plurality of transistors.

16. The semiconductor substrate of claim 8, wherein the substrate comprises a silicon substrate.

17. A display panel, comprising:
at least two first electrodes spaced apart from each other on a substrate;
a buried pattern between the at least two first electrodes, the buried pattern including a conductive material;
a dielectric pattern between the buried pattern and each of the at least two first electrodes;
a second electrode covering the at least two first electrodes, the buried pattern, and the dielectric pattern; and
a liquid crystal layer between the second electrode and each of the at least two first electrodes, the buried pattern, and the dielectric pattern.

18. The display panel of claim 17, wherein the at least two first electrodes and the buried pattern comprise metal.

19. The display panel of claim 17, further comprising:
a plurality of transistors on the substrate and connected to corresponding ones of the at least two first electrodes, each of the plurality of transistors including a gate electrode on the substrate, a source region on the substrate on a first side of the gate electrode and a drain region on the substrate on a second side of the gate electrode, wherein
each of the at least two first electrodes is connected to the drain region of corresponding one of the plurality of transistors .

20. The display panel of claim 17, wherein a height of a top surface of the buried pattern from the substrate is greater than that of a top surface of the dielectric pattern.
